(19) United States
(12) Patent Application Publication
(10) Pub. No.: US 2009/0176368 A1
(43) Pub. Date: Jul. 9, 2009

(54) MANUFACTURING METHOD FOR AN INTEGRATED CIRCUIT STRUCTURE COMPRISING A SELECTIVELY DEPOSITED OXIDE LAYER

(76) Inventors: Nan Wu, Dresden (DE); Hans Lindemann, Dresden (DE); Johannes von Kluge, Dresden (DE)

Correspondence Address: COATS & BENNETT/QIMONDA, 1400 CRESCENT GREEN, SUITE 300, CARY, NC, 27518, US

(21) Appl. No.: 11/970,673

(22) Filed: Jan. 8, 2008

(51) Int. Cl. H01L 21/44

(52) U.S. Cl. 438/685; 257/E21.476

(57) ABSTRACT

The present invention provides a manufacturing method for an integrated circuit structure comprising a selectively deposited oxide layer. An integrated circuit structure including a first and second region is provided, the first region being a metal region and the second region being a non-metal region. Then an oxide layer is selectively depositing on the first and second regions. The oxide layer forms a first thickness on the first region and a second thickness on the second region, the first thickness being larger than the second thickness.

### BACKGROUND OF THE INVENTION

1. Field of the Invention

The present invention generally relates to a manufacturing method for an integrated circuit structure comprising a selectively deposited oxide layer.

2. Related Art

The packing density of devices in integrated circuits is continuously increasing from generation to generation. An aspect to be always considered is the quality of electrical insulation of the devices against each other.

There are various methods to form oxide insulation regions in integrated circuit structures. Chemical vapour deposition (CVD) of silicon oxide is widely used in VLSI circuits as insulating material deposition method. Step coverage, void-free behaviour, density, purity etc. are the main quality parameters of the deposited oxide material.

With the continuous downscaling of features sizes, the process becomes more and more challenging due to increased gap aspect ratio, complex structures, complex materials exposed under the deposition process, and complex integration schemes.

A known selective oxide CVD process (SelOx) deposits silicon oxide on a crystalline silicon surface, but not on silicon nitrate, polysilicon, amorphous silicon, silicon oxide. Such a SelOx process is used for STI (shallow trench insulation) fills in integrated circuit structure technologies down to 70 nm.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

Figures:

FIG. 1A-C show an approach of a manufacturing method for integrated circuit structure comprising selectively deposited oxide layer;

FIG. 2A-C show a further approach of a manufacturing method for integrated circuit structure comprising selectively deposited oxide layer;

FIG. 3 shows a further approach of a manufacturing method for integrated circuit structure comprising selectively deposited oxide layer; and

FIG. 4A-F show a further approach of a manufacturing method for integrated circuit structure comprising selectively deposited oxide layer, namely FIGS. 4A, 4D along a first cross section, FIGS. 4B, 4E along a second cross section, and FIGS. 4C, 4F along a third cross section.

In the Figures, identical reference signs denote equivalent or functionally equivalent components.

### DETAILED DESCRIPTION

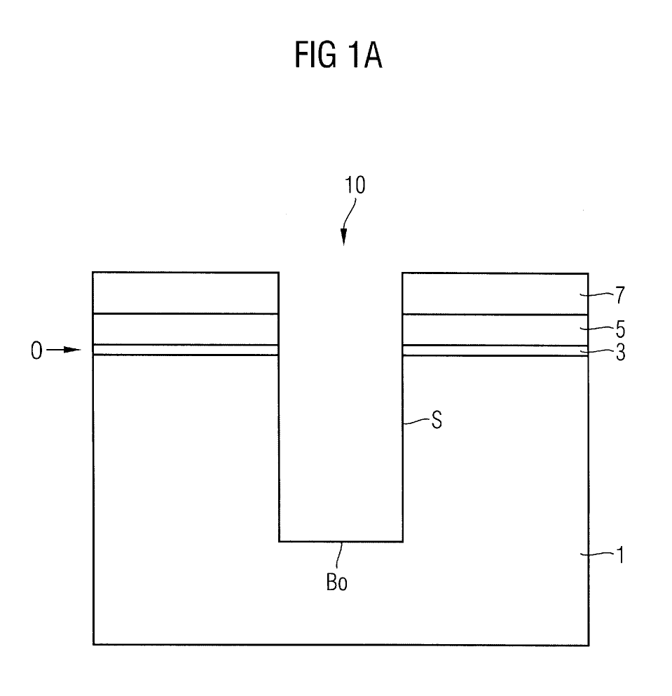

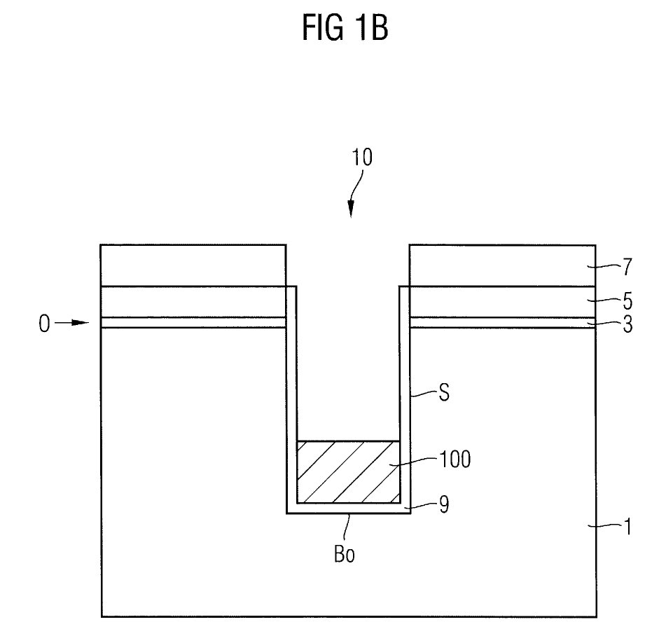

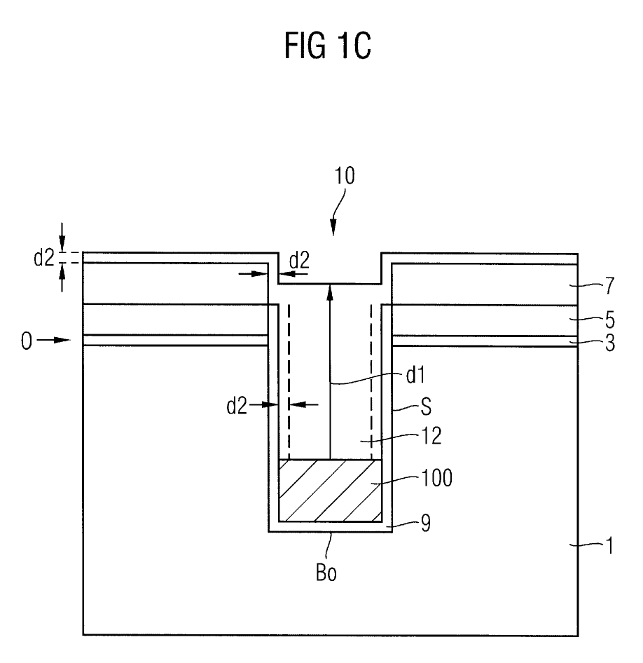

FIG. 1A-C show an approach of a manufacturing method for integrated circuit structure comprising selectively deposited oxide layer.

In FIG. 1A, reference sign 1 denotes a semiconductor substrate, e.g. a silicon substrate. On an upper surface O of the substrate 1 there are a pad oxide layer 3, a polysilicon layer 5, and a silicon nitride layer 7. It should be mentioned that it is also possible to have a single cover layer instead of the three layers 3, 5, 7.

A trench 10 having a bottom BO and a sidewall S is formed in the substrate 1 and the layers 3, 5, 7.

In this example, the structure of FIG. 1A is the starting point for forming a conductor line, e.g. a buried word line or bit line, in the trench 10 and for forming source/drain regions in the polysilicon layer 5.

With respect to FIG. 1B, a dielectric 9, f.e. a gate dielectric, is provided on the sidewall S and the bottom of the trench 10. Thereafter, a tungsten metal layer or other metal layer is deposited over the entire structure and recessed back in the trench 10 to below the upper surface O of the substrate 1. Thus, a conductor line 100 has been formed.

Further, with respect to FIG. 1C, the process of burying the conductor line 100 under a silicon oxide is described. Namely, a selective chemical vapour deposition (SelOx) is performed, wherein the oxide layer forms with a first thickness d1 on the tungsten conductor line 100 and with a second thickness d2 on the silicon nitride layer 7 and on the dielectric layer 9 and on the polysilicon layer 5. The first thickness is e.g. about of a factor of 3-5 higher than the second thickness d2. Thus, in this SelOx process, which selectively deposits silicon oxide on the tungsten metal conductor line 100 in comparison to the silicon nitride layer 7, it is possible to completely fill the trench 10 in the substrate 1 with silicon oxide. Because of the metal seeding in the trench bottom BO a bottom-up void-free deposition behaviour can be achieved.

It should be mentioned that tungsten as a metal for the buried wordline 100 is only one example where the selective deposition process can be performed. There is a variety of other metals for which such a selective deposition process can be performed such as Ti, TiN, W, AlCu, and many more metal conductor materials which become readily apparent for the average person skilled in the art.

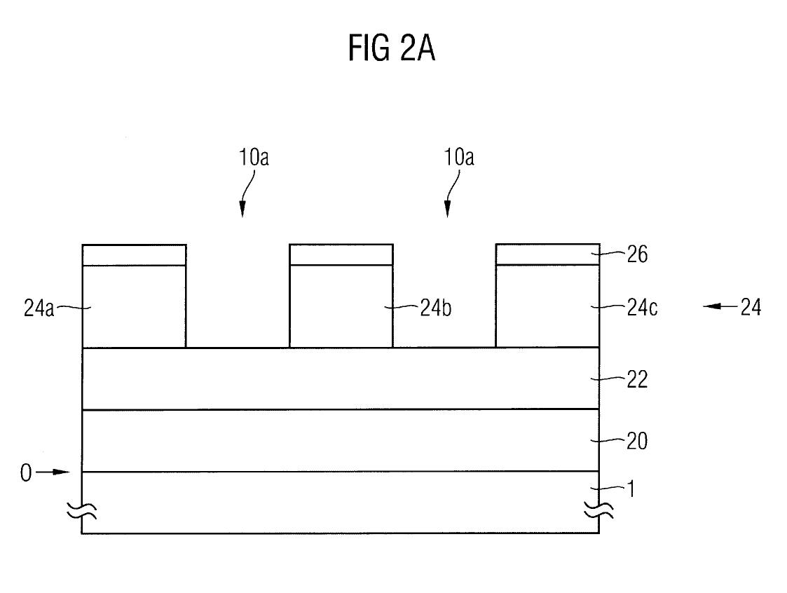

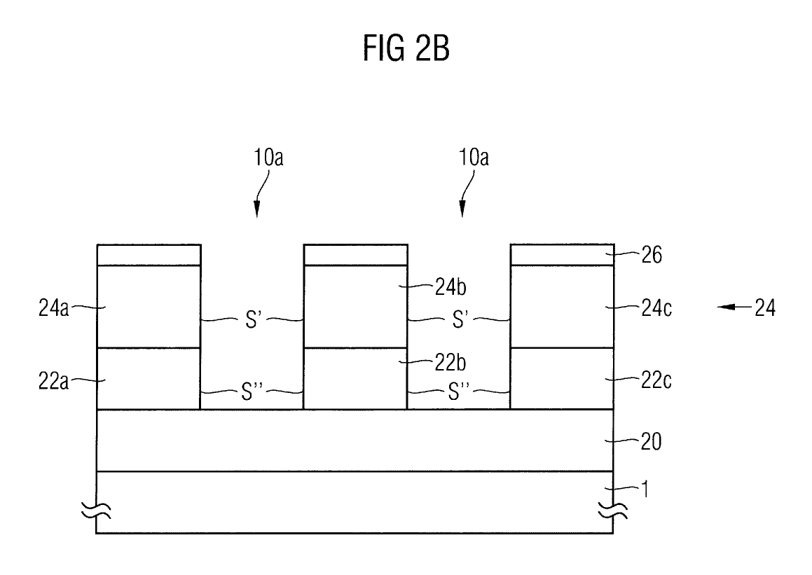

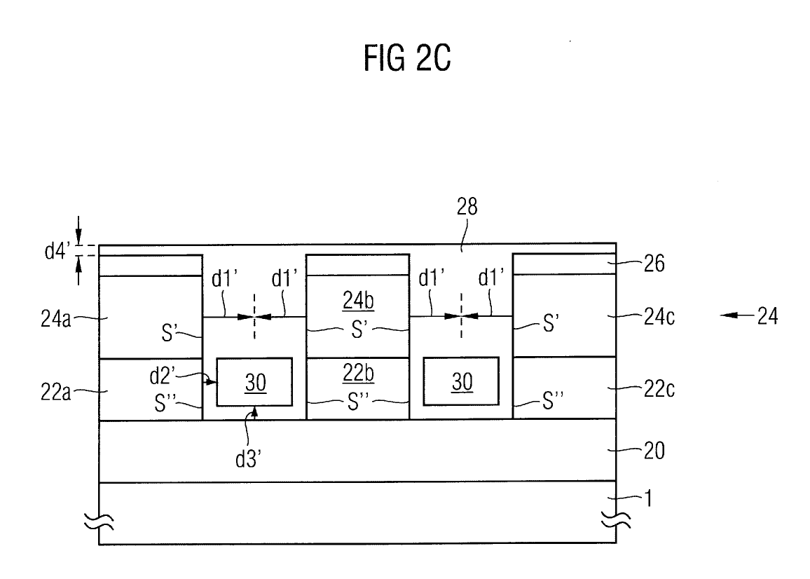

FIG. 2A-C show a further approach of a manufacturing method for integrated circuit structure comprising selectively deposited oxide layer.

In FIG. 2A, reference sign 1 denotes a semiconductor substrate, e.g. a silicon substrate, having an upper surface O. Integrated in the substrate 1 is a (not shown) circuit structure. Reference sign 20 denotes a cap nitride layer, e.g. a gate contact cap nitride layer. It should be mentioned that further layers could be provided between layers 1 and 20 depending on the specific integrated circuit details. It is also possible that layer 20 is a metal layer. Also, layer 20 may be structured or not structured.

On the cap nitride layer 20 there is an insulating layer 22 formed of a silicate glass, e.g. boro-phosphorous silicate glass (BPSG). Above the insulating layer 22 a first metal layer including neighbouring metal conductor lines 24a, 24b, 24c is provided. For example, the metal conduction lines 24a, 24b, 24c are made of titanium. Neighbouring conductor lines 24a, 24b and 24b, 24c are separated by a respective intervening space 10a. On top of the conductor lines 24a, 24b, 24c there is an insulator hard mask layer 26, e.g. made of oxide, by use of which the conductor lines 24a, 24b, 24c have been formed.

In a subsequent process step which is depicted in FIG. 2B, the insulating layer 22 between the conductor lines 24a, 24b, 24c is etched down to the cap nitride layer 20, thus forming insulator lines 22a, 22b, 22c arranged under a respective corresponding conductor line 24a, 24b, 24c. The sidewalls S′ of neighbouring metal conductor lines 24a, 24b and 24b, 24c and the sidewalls S″ of neighbouring insulator lines 22a, 22b and 22b, 22c are facing each other.

In a subsequent process step which is illustrated in FIG. 2C an oxide layer 28 is selectively deposited on the structure of FIG. 2B. In this SelOx process, the oxide layer 28 forms a first thickness d1′ on the facing sidewalls S′ of the neighbouring metal conductor lines 24a, 24b and 24b, 24c. Moreover, the oxide layer 28 forms a second thickness d2′ on the facing sidewalls S″ of the neighbouring insulator lines 22a, 22b and 22b, 22c. The first thickness d1′ is about a factor of two larger than the second thickness d2′. In addition, the oxide layer 28 forms a third thickness d3′ on the cap nitride layer 20 and a fourth thickness d4′ on the oxide hard mask layer 26, said third thickness d3′ and said fourth thickness d4′ being approximately the same as the second thickness d2′.

Consequently, this SelOx process leads to a respective void or air gap 30 between neighbouring insulator lines 22a, 22b and 22b, 22c. By forming these voids 30 the gap between neighbouring metal conductor lines 24a, 24b and 24b, 24c can be closed fast due to the higher deposition rate of the oxide layer 28 on the metal conductor lines 24a, 24b, 24c.

By leaving voids or air gaps 30 between neighbouring insulator lines 22a, 22b and 22b, 22c the parasitic capacitance between conductor lines 24a, 24b, 24c can be reduced which facilitates the realization of long conductor lines, e.g. long bit lines of a semiconductor memory device.

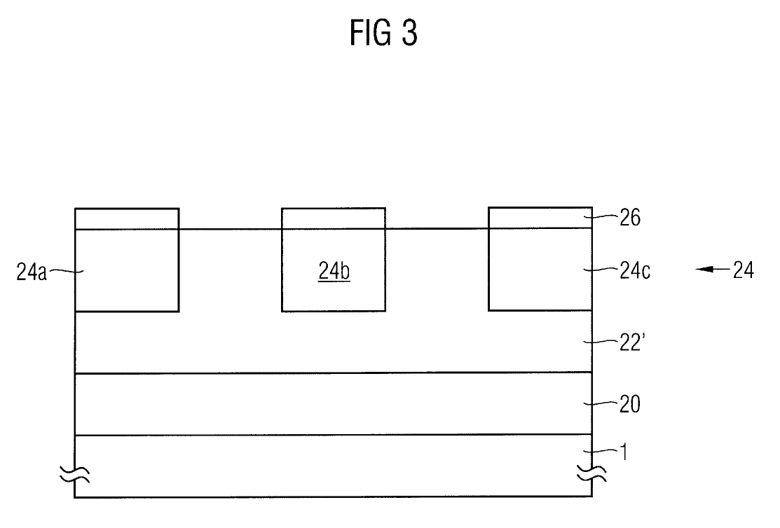

FIG. 3 shows a further approach of a manufacturing method for integrated circuit structure comprising selectively deposited oxide layer.

The approach shown in FIG. 3 is nearly identical to the approach explained above with respect to FIGS. 2A-C except that the metal conductor lines 24a, 24b, 24c have been created in a damascene technique embedded in the insulating layer 22′. Therefore, starting with a process status of FIG. 3, the remaining insulating layer between the neighbouring metal conductor lines 24a, 24b, 24b, 24c has to be removed in the etch step using the oxide hard mask layer 26.

It should be mentioned that in the approaches explained above, the voids or air gaps 30 have been created between the insulator lines under the first metal level 24 and above the uppermost circuit level. However, it is of course possible to create the voids or air gaps 30 also between neighbouring metal levels.

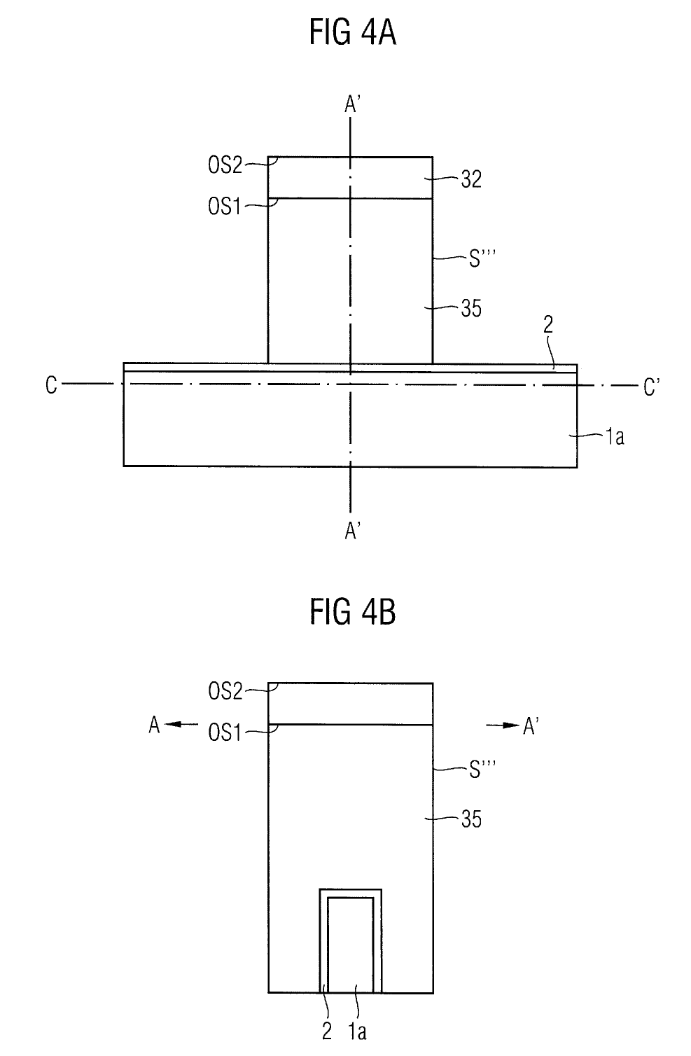

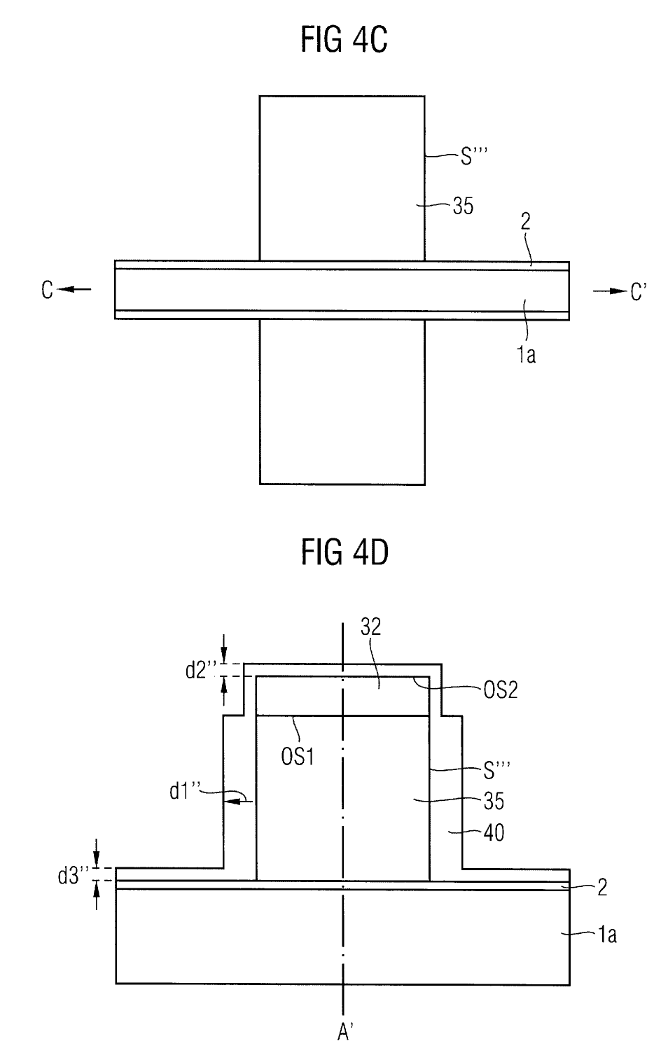

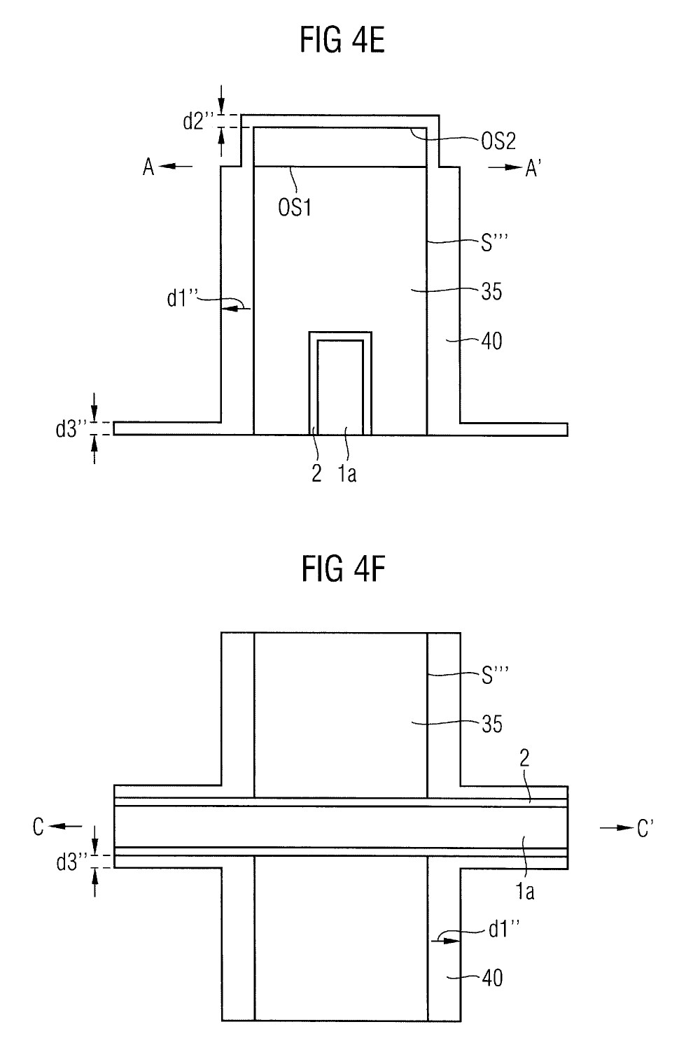

FIG. 4A-F show a further approach of a manufacturing method for integrated circuit structure comprising selectively deposited oxide layer, namely FIGS. 4A, 4D along a first cross section, FIGS. 4B, 4E along a second cross section, and FIGS. 4C, 4F along a third cross section.

The approach shown in FIGS. 4A-F refers to a FinFET device. As becomes apparent from FIGS. 4A, B, C a silicon fin 1a has been formed on a silicon semiconductor substrate. The fin 1a is covered by a gate dielectric layer 2, e.g. made of silicon oxide. Reference sign 35 denotes a tungsten metal gate embracing the fin 1a and gate dielectric layer 2 as becomes clear from FIG. 4B. On the upper surface OS1 of the metal gate 35 there is a nitride cap 32 having an upper surface OS2. The sidewall of the metal gate 35 is denoted by reference sign S′″.

As depicted in FIGS. 4D, E, F in a subsequent process step a spacer 40 is formed around the metal gate 35 by a selective oxidation process (SelOx). The oxide spacer 40 forms a first thickness d1″ on the sidewall S″′ of the metal gate 35, whereas it forms a second thickness d2″ on the nitride cap 32 and a third thickness d3″ on the gate dielectric layer 2. The first thickness d1″ is a factor of three larger than the second and third thickness d2″, d3″.

Since the metal gate 35 of the FinFET of this approach has a complex topography, i.e. the sidewall S′″ having different extensions in the different cross-sections of FIGS. 4A, 4B, 4C and FIGS. 4D, 4E, 4F this selective oxidation method allows a simple deposition of the oxide spacer 40 which adopts the same complex topography.

It should be mentioned that the selective deposition process of silicon oxide on metal regions is not limited to the examples shown here above, but are principally applicable for all structures having metal and non-metal regions where a selective deposition on the metal regions is desired. The self-align behaviour for cases where an insulator is only needed on the surface of a conductor can be used for any kind of integrated circuit structure and facilitates a downscaling to continuously shrinking feature sizes.

Other systems, methods features and advantages of the invention will be or will become apparent to one with skill in the art. It is intended that all such additional systems, methods, features and advantages be included within this description, be within the scope of the invention, and be protected by the accompanying claims.

1. A manufacturing method for an integrated circuit structure comprising a selectively deposited oxide layer, the method comprising:
providing an integrated circuit structure including a first and second region, the first region being a metal region and the second region being a non-metal region;
selectively depositing an oxide layer on the first and second regions;
wherein the oxide layer forms a first thickness on the first region and a second thickness on the second region, the first thickness being larger than the second thickness.

2. The manufacturing method of claim 1, wherein the first thickness is at least a factor of two larger than the second thickness.

3. The manufacturing method of claim 1, wherein the integrated circuit structure comprises a trench formed in a substrate and a recessed metal fill in the trench, wherein the first region is located on an upper surface of the recessed metal fill and the second region is located on or above a sidewall of the trench, and wherein selectively depositing is performed such that the trench is filled by the oxide layer.

4. The manufacturing method of claim 3, wherein the substrate is a silicon substrate.

5. The manufacturing method of claim 4, wherein the integrated circuit structure comprises a liner formed on the sidewall, and wherein the second region is a surface of the liner.

6. The manufacturing method of claim 3, wherein the recessed metal fill is a conductor line.

7. The manufacturing method of claim 6, wherein the conductor line is a buried wordline or bitline of a memory device.

8. The manufacturing method of claim 1, wherein the integrated circuit structure comprises a conductor line formed on a substrate and a cap layer formed on an upper surface of the conductor line, wherein the first region is located on a sidewall of the conductor line and the second region is located on an upper surface of the cap layer.

9. The manufacturing method of claim 8, wherein the conductor is a gate electrode of a FinFET embracing a fin formed on the substrate covered by a gate dielectricum.

10. A manufacturing method for an integrated circuit structure comprising a selectively deposited oxide layer, the method comprising:
providing an integrated circuit structure including a first and second metal conductor line arranged on a corresponding first and second insulator line above a substrate and being separated by an intervening space such that the sidewalls of the first and second metal conductor lines and the sidewalls of the first and second insulator lines on the side of the space are facing each other;
selectively depositing an oxide layer on the facing sidewalls of the first and second metal conductor line and the sidewalls of the first and second insulator lines, wherein an oxide layer forms a first thickness on the facing sidewalls of the first and second metal conductor lines and a second thickness on the facing sidewalls of the first and second insulator lines, the first thickness being larger than the second thickness.

11. The manufacturing method of claim 10, wherein the first thickness is at least a factor of two larger than the second thickness.

12. The manufacturing method of claim 10, wherein the space is completely filled between the first and second metal conductor lines and the space is partially filled between the first and second insulator lines.

13. The manufacturing method of claim 12, wherein the integrated circuit structure includes a structure on the bottom of the space and the oxide layer is selectively deposited on the bottom structure forming a third thickness, the first thickness being larger than the third thickness, such that a void is formed between the first and second insulator lines.

14. The manufacturing method of claim 13, wherein the first thickness is at least a factor of two larger than the third thickness.

15. The manufacturing method of claim 13, wherein the bottom structure comprises an insulator.

16. The manufacturing method of claim 13, wherein the bottom structure comprises a metal.

17. The manufacturing method of claim 1, wherein the metal region comprises at least one of the group of Ti, TiN, W, AlCu.

18. The manufacturing method of claim 10, wherein the metal conductor line comprises at least one of the group of Ti, TiN, W, AlCu, Cu, TaN.
